(19) United States
(12) Patent Application Publication
(10) Pub. No.: US 2026/0206171 A1
(43) Pub. Date: Jul. 16, 2026

(54) NON-POWERED RACK CHASSIS SYSTEMS

(71) Applicant: Nvidia Corporation, Santa Clara, CA (US)

(72) Inventors: Elad Mentovich, Tel Aviv (IL); David Mohr, Houston, TX (US); Ryan Albright, Beaverton, OR (US); Ryan Wells, Raleigh, NC (US); Fan Yu, Santa Clara, CA (US)

(21) Appl. No.: 19/020,766

(22) Filed: Jan. 14, 2025

(51) Int. Cl. H05K 7/14

(52) U.S. Cl. CPC H05K 7/1492

(57) ABSTRACT

Systems and methods disclosed herein can be used to provide power for a non-powered rack chassis. An enclosure shaped to fit within the non-powered rack chassis may be associated with or may include a power shelf. The power shelf may have at least one busbar to distribute the power from the power shelf to one or more sleds of the non-powered rack chassis.

### TECHNICAL FIELD

This disclosure relates to power distribution within a datacenter, and in at least one embodiment pertains to power distribution for a non-powered rack chassis of a datacenter.

### BACKGROUND

A rack of a datacenter may include at least one busbar built or installed directly into the rack to distribute power to servers within the rack. The rack represents a powered rack chassis for at least having a busbar built or installed directly into the rack. Installation of certain hardware and cables for a rack in a datacenter may require access to a cold aisle side of the datacenter for at least the power connections and other features of the rack. While datacenters can support cable installation for at least network cables from the hot aisle side, space constraints may limit such access in a datacenter and may make it difficult to complete power connections to a rack.

### BRIEF DESCRIPTION OF DRAWINGS

FIG. 1 illustrates a datacenter that is subject to embodiments associated with a non-powered rack chassis having an enclosure with a power shelf and a busbar for one or more sleds of the enclosure;

FIG. 2A illustrates rack options for a non-powered rack chassis having an enclosure with a power shelf and a busbar for one or more sleds of the enclosure, according to at least one embodiment;

FIG. 2B illustrates enclosure options for a non-powered rack chassis having an enclosure with a power shelf and a busbar for one or more sleds of the enclosure, according to at least one embodiment;

FIG. 3A illustrates power distribution aspects in a system for a non-powered rack chassis having an enclosure with a power shelf and a busbar for one or more sleds of the enclosure, according to at least one embodiment;

FIG. 3B illustrates further power distribution aspects in a system for a non-powered rack chassis having an enclosure with a power shelf and a busbar for one or more sleds of the enclosure, according to at least one embodiment;

FIG. 4 illustrates computer and processor aspects for a non-powered rack chassis having an enclosure with a power shelf and a busbar for one or more sleds of the enclosure, according to at least one embodiment;

FIG. 5 illustrates a process flow for a non-powered rack chassis, according to at least one embodiment;

FIG. 6 illustrates yet another process flow in a system of a non-powered rack chassis, according to at least one embodiment;

FIG. 7 illustrates a further process flow in a system having a non-powered rack chassis, according to at least one embodiment; and

FIG. 8 illustrates an example datacenter to apply at least one embodiment in FIGS. 1-7.

### DETAILED DESCRIPTION

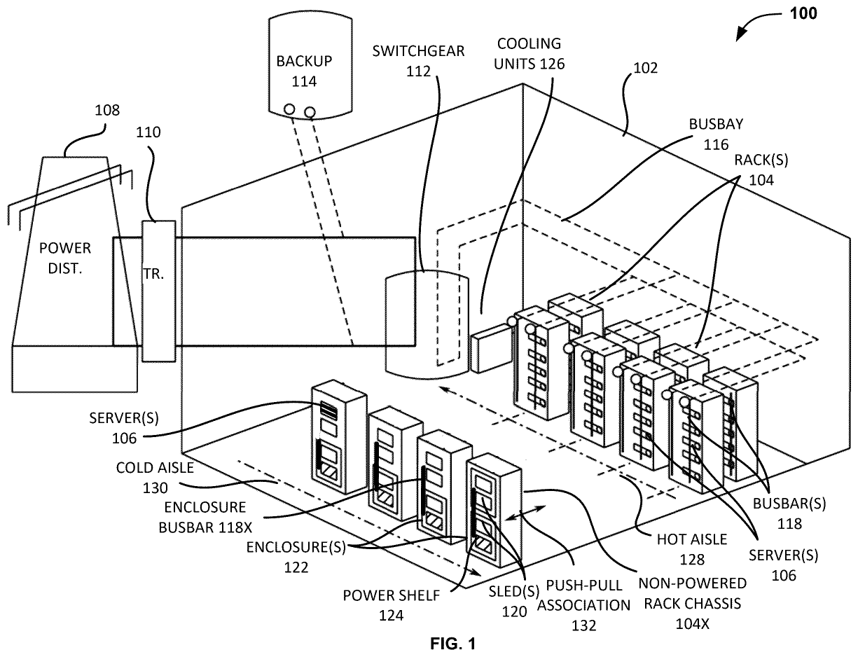

FIG. 1 illustrates a datacenter 100 that is subject to embodiments associated with providing power and computing in a non-powered rack chassis using an enclosure with a power shelf and a busbar for one or more sleds of the enclosure. A non-powered rack chassis, as used herein, may be in reference to a bare metal rack that may be without power components, including components with an ability to receive power into the rack and to distribute power to compute devices and other devices of the rack. An enclosure, as used herein, may be in reference to a bare metal frame that is configured or shaped to fit within a non-powered rack chassis. For instance, the enclosure may include dimensions that are within dimensions (and tolerances) of the non-powered rack chassis.

A power shelf, as used herein, may be in reference to a tray or similar modular frame that may include power input features (such as a clip or socket) to receive power, power conditioning features (such as converters or rectifiers, correctors, monitors, and balancers) to condition the power for compute devices or other devices, and power distribution features (such as enclosure busbars) to distribute the power for the compute devices or other devices. The power shelf may be configured by, for instance, dimensions that are within an enclosure's dimensions (and tolerances) of an enclosure, to fit within the enclosure or to fit within the non-powered rack chassis. At least the power distribution feature may be provided in the power shelf, in one example, and may be provided in the enclosure, in another example. When power is to be provided from the enclosure, the power distribution feature of the power shelf may be coupled to a distribution outlet of the power shelf. The enclosure may be removably associated with a non-powered rack chassis to provide the power from within the enclosure.

The datacenter 100 may be subject to multiple sleds 120 installed in individual enclosures 122 for the non-powered rack chassis 104X. These non-powered rack chassis 104X may be distinct from certain racks 104 that may be otherwise within the datacenter 100, that may be associated with servers 106 therein (in a server tray, server box, or server module format), and that may include compute devices therein to perform a workload. Such racks 104 may be tied (such as hardwired or natively within rows of racks) as part of the infrastructure of the datacenter 100. The non-powered rack chassis 104X, on the other hand, may be imparted with workload-performing capabilities by at least the enclosure 122 and the power shelf 124 that may be self-contained unit. The self-contained unit includes the aforementioned power capabilities, compute devices, and other devices (such as cooling devices) to perform the workload. The non-powered rack chassis 104X, being imparted with the workload-performing capabilities, may not be tied (hardwired or natively within rows of racks) to the infrastructure of the datacenter 100.

For instance, while the racks 104 may be associated with power supply units (PSUs) and may be associated with a busbay 116 to receive and distribute power for the servers 106, these racks 104 may necessarily include power components (such as busbars 118) that are intimately associated with the racks 104. The power components may be part of the infrastructure of the datacenter 100. Differently, the non-powered rack chassis 104X, being a bare metal rack without busbars or PSUs, may not be able to receive and distribute power by itself. Instead, the non-powered rack chassis 104X may be highly scalable by at least capability to add and remove self-contained enclosures to the non-powered rack chassis 104X. The enclosures may have a power shelf and sleds to provide power and computing in a non-powered rack chassis 104X.

The scalability by use of an enclosure may be in the form of different power levels, compute devices, and other devices that may be associated with the non-powered rack chassis 104X at any time depending on the type of workload to be performed. The scalability can address changes in demands from workloads in the datacenter 100. The compute devices may be provided on circuit boards and may include processors (such as central processing units (CPUs), graphics processing units (GPUs), data processing units (DPUs), or the like), and other components (such as memory, communication modules, input/output modules, and the like). The other devices may include the cooling devices that may be powered from the enclosure 122 or the power shelf 124.

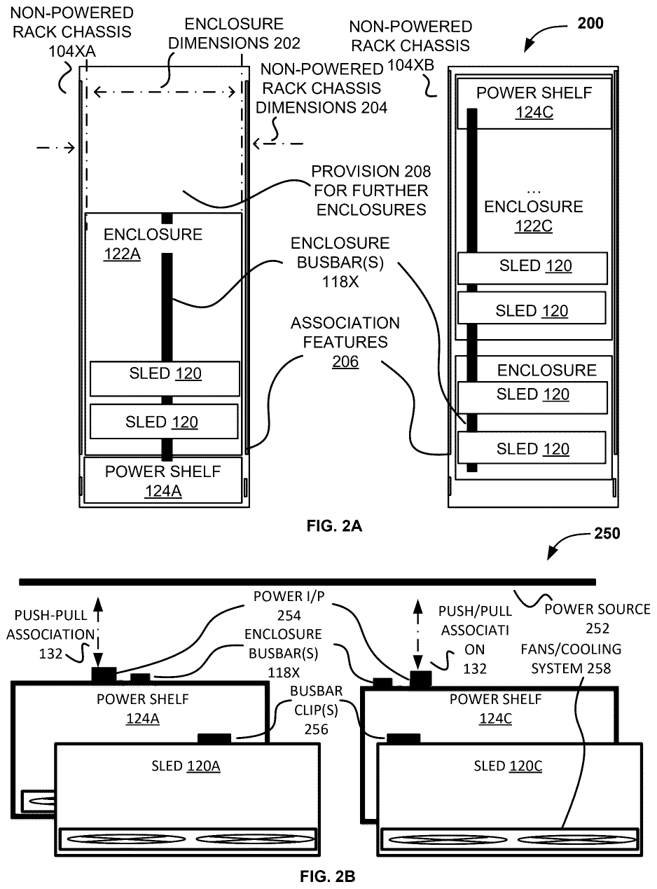

The enclosure 122 may have one or more sleds 120 in a 1U to 3U format. The enclosure 122 may include a power shelf 124 in a 1U to 3U format. The enclosure 122 or its power shelf 124 may include at least one enclosure busbar 118X to be used with a non-powered rack chassis 104X so that the power shelf 124 can receive power and can distribute power through the enclosure busbar 118X to the one or more sleds 120 that may be independent of a power requirement in the non-powered rack chassis 104X. For all intents and purposes, a busbar described in connection with power provided from a power shelf may be treated as an enclosure busbar 118X. The enclosure 122 may be shaped (such as by the enclosure dimensions 202 in FIG. 2A) to fit within a non-powered rack chassis 104X by a push-and-pull association 132 (or sliding in or out association). The enclosure dimensions 202 may include, in consideration, non-powered rack chassis dimensions 204 and tolerances from the association features 206. The enclosure 122, having at least the power features, such as the power shelf 124 and the enclosure busbar 118X pre-installed therein, may be able to support the power demands of the one or more sleds.

The power shelf 124 and the enclosure busbar 118X may support additional enclosures 122 that may not have its own power shelf 124 and that may be within the same non-powered rack chassis 104X. The enclosures 122 may all be configured for a plug-and-play installation within the non-powered rack chassis 104X and can be installed from the hot aisle side of a datacenter. The enclosures 122 may also be configured so that the non-powered rack chassis 104X can be installed from the cold aisle side. For instance, the enclosures 122 may include a fan configured for directional changes and to be used from the hot aisle side or the cold aisle side. This approach may be able to address hardware installation and installation of cables for a rack in a datacenter 100 which may require access to the cold aisle side of the datacenter for at least the power features of the rack, even if a datacenter 100 can support network cabling from the hot aisle side. The ability of an enclosure 122 that is dimensioned to fit within a non-powered rack chassis 104X by sliding in and out and that has at least the power features, such as the power shelf and the busbar pre-installed therein, allows the enclosure to be associated with the non-powered rack chassis 104X from the hot aisle 128 side of a datacenter 100 without need to access the cold aisle 130 side.

In at least one embodiment, the datacenter 100 may include one or more rooms 102 of racks 104, where the racks 104 may include server trays or servers 106. The datacenter 100 may be powered from a power distribution 108 system, via one or more transformers 110 (Tr.), so that the power to a switchgear 112 may be suitable for the datacenter. For instance, the power distribution 108 system may be part of a transmission system. The transmission system may provide high-voltage electricity from a utility grid. Each transformer 110 may step down the voltage to a level suitable for the datacenter's equipment and devices, such as the aforementioned processors that may be in the server trays or servers 106 in each rack 104.

The switchgear 112 may be able to control, protect, and isolate power in both downstream and upstream directions. The switchgear 112 may be used to manage flow of electricity in a reliable and efficient manner using switching of electrical circuits for controls and using breakers and fuses to detect and respond to faults or overloads in both downstream and upstream directions. In addition to an external source represented by the transmission systems and to ensure uninterrupted power supply, a backup 114 system, such as a generator or Uninterruptible Power Supply (UPS), may be used with the power distribution 108 system (Power Dist.). In addition, a cooling system 126 may provide at least air cooling for the cold aisle 130 side and passing through the racks 104 and the non-powered rack chassis 104X to the hot aisle 128 side of the datacenter 100. The movement of the air cooling may be supported by fans of the enclosures 122, in one example.

The switchgear 112 may be associated with the busbay 116. The busbay 116 may provide power to one or more racks 104 and may allow the enclosure 122 to receive power for the non-powered rack chassis 104X. In one example, the busbay 116 may provide power to one or more racks 104 through provided busbars 118, while the enclosure 122 may receive power using a power input (I/P) (in FIG. 2B) of the power shelf 124. The busbars 118 and the enclosure busbars may be conductive bars that carry electrical current to various loads, including those represented by the aforementioned processors, that may be within the server trays or computer modules (also referenced as servers 106) in each rack 104 of the datacenter 100 or within the sleds 120 of the enclosures 122 herein. The server trays or servers 106 in each rack 104 of the datacenter 100 may not be self-sufficient, with respect to at least power requirements, relative to the enclosures 122 herein. The busbars 118 and the enclosure busbars 118X may be provided from copper, aluminum, or a suitable power delivery material. The busbars 118 and the enclosure busbars 118X may be able to work together to handle the high-current demands of the datacenter 100.

FIG. 2A illustrates rack options 200 for a non-powered rack chassis having an enclosure with a power shelf and a busbar for one or more sleds of the enclosure, according to at least one embodiment. In one instance, a system for powering a non-powered rack chassis 104X may include an enclosure 122 having dimensions 202 that allow a shape for the enclosure 122 to fit within rack dimensions 204 of the non-powered rack chassis 104X. Although illustrated in two dimensions, it can be appreciated that the dimensions 202 of the enclosure 122 and the rack dimensions 204 may include a third dimension of depth to also contribute to the shape allowing the fit between the enclosure 122 and the non-powered rack chassis 104X. In one example, one or more of the non-powered rack chassis 104X or the enclosure 122 may have association features 206 to support the inclusion of the enclosure 122 into the non-powered rack chassis 104X. The association features 206 may be tracks, wheels, or other guidance and retention components to guide and retain the enclosure 122 in a releasable manner.

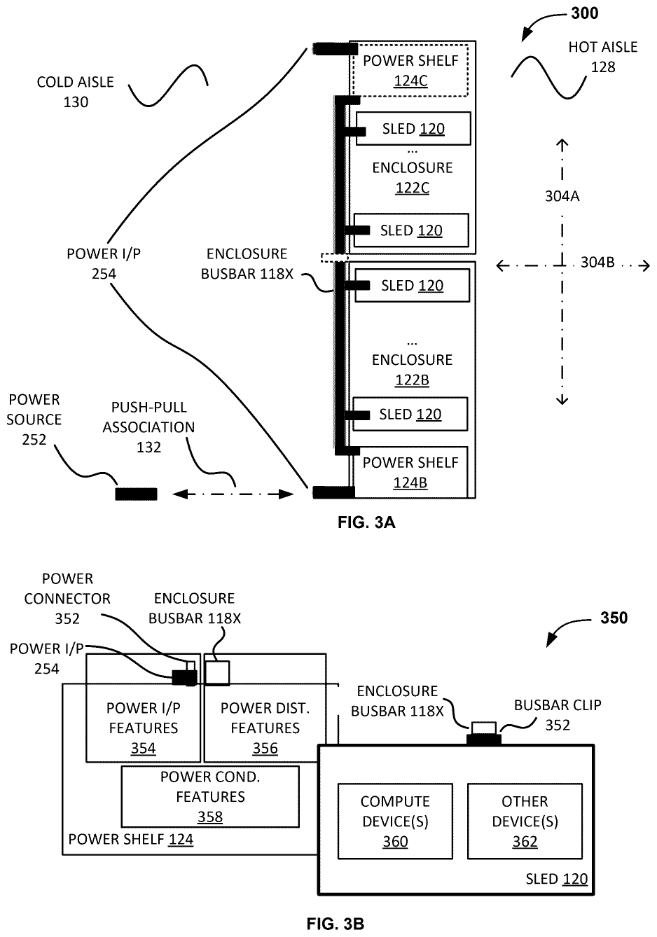

The system for powering a non-powered rack chassis 104X may include a power shelf 124 to power one or more sleds 120 within the enclosure 122. The power shelf 124 may be in a server tray, box, or module 1U to 3U format and may be provided at a top or a bottom of the non-powered rack chassis 104X. The power shelf 124 may be provided within the enclosure 122. For instance, the power shelf 124 may be provided at a top or a bottom of the enclosure 122. The one or more sleds 120 may include one or more circuit boards with compute devices and with other devices (as in FIG. 3B). The powering of the one or more sleds 120 may be with reference to powering one or more of the compute devices or the other devices within the one or more sleds 120.

In one example, each sled 120 of each enclosure 122 may perform a different workload. In another example, each sled 120 may be part of a same workload performed in parallel where each sled 120 is in continuous interaction with the other sleds of the same enclosure 122. The sleds 120 that are in the same enclosure 122 may altogether perform aspects of a same workload. In yet another example, sleds 120 in two or more enclosures may be associated with the same workload or different parts of the same workload. In one example, FIG. 2A illustrates a provision 208 for further enclosures.

The system for powering a non-powered rack chassis 104X may include at least one enclosure busbar 118X of the power shelf 124 or the one or more sleds 120 to distribute power from the power shelf 124. The enclosure busbar 118X may extend from the power shelf 124, through a back of the enclosure 122, to allow one or more sleds 120 within the enclosure to connect to it. In FIG. 2A, a left-side non-powered rack chassis 104XA and a right-side non-powered rack chassis 104XB are illustrated. The left-side non-powered rack chassis 104XA includes at least one enclosure 122A and one power shelf 124A. The power shelf 124A is illustrated as outside the enclosure 122A. The power shelf 124A may be a lowest feature of the non-powered rack chassis 104XA. The power shelf 124A has an enclosure busbar 118X extending upwards to allow attachments from one or more sleds 120. The enclosure busbar 118X in the left-side non-powered rack chassis 104XA is illustrated as contained within the enclosure 122A. There may be a provision 208 for further enclosures 122 that may be with or without respective power shelfs 124. The enclosure busbar 118X for the left-side non-powered rack chassis 104XA is illustrated at a center of the non-powered rack chassis 104XA. In another example, the enclosure busbar 118X for the right-side non-powered rack chassis 104XB may be on a side (left or right) of the non-powered rack chassis 104XB.

The right-side non-powered rack chassis 104XB illustrates that there may be multiple enclosures 122B, 122C provided in a non-powered rack chassis 104XB. The right-side non-powered rack chassis 104XB also illustrates that a power shelf 124C may be within the enclosure 122C. Each enclosure 122B, 122C may have its own power shelf 124, but in the example of FIG. 2B, the top enclosure 122C provides a power shelf 124C that may be utilized by both enclosures 122B and 122C. Further, the power shelf 124C is illustrated at a top of the enclosure 122C and also at a top of the non-powered rack chassis 104XB. An enclosure busbar 118X is illustrated as extending from the power shelf 124C to allow power for both enclosures 122B, 122C. The sleds 120 in both enclosures 122B, 122C and attach to and use power from the enclosure busbar 118X.

FIG. 2B illustrates enclosure options 250 for a non-powered rack chassis having an enclosure with a power shelf and a busbar for one or more sleds of the enclosure, according to at least one embodiment. The enclosure options 250 illustrate that an enclosure 122 may be configured for a plug-and-play installation, with respect to coupling of the enclosure 122 to a power source 252. The coupling may be with respect to the power I/P 254 being associated to the power source 252 to allow power to the power shelf 124A, 124C. FIG. 2B illustrates the locations of the power I/P 254 for an individual power shelf 124A, 124C may be based in part on the non-powered rack chassis 104XA, 104XB, with which it is to be associated. The plug-and-play installation for the coupling may be by a push-and-pull association 132 of an enclosure 122A, 122C within the non-powered rack chassis 104XA, 104XB. The plug-and-play installation may also be with respect to providing the power for the one or more sleds 120 using the power shelf 124A, 124C and the enclosure busbar 118X, while the enclosure 122A, 122C is within the non-powered rack chassis 104XA, 104XB.

In one example, there may be power connectors 352 (in FIG. 3B) to be used with the power I/P 254 of the power shelf 124A, 124C. The power connectors 352 may allow association with the power source 252 via mating features of the side of the power source 252. The enclosure 122A, 122C may be configured to be installed into the non-powered rack chassis 104XA, 104XB from a hot aisle 128 side of a datacenter 100 by the push-and-pull association 132. Further, the one or more sleds 120 and the power shelf 124A, 124C may include one or more fans 258 that may be configured for directional changes. This may be so that the one or more fans 258 may be switched so that airflow for cooling within the enclosure 122A, 122C flows from a cold aisle 130 side to the hot aisle 128 side of a datacenter 100. FIG. 2B also illustrates a busbar clip 256 that may be available in each sled 120A, 120C to allow push-and-pull association with the enclosure busbar 118X of the power shelf.

FIG. 3A illustrates power distribution aspects 300 in a system for a non-powered rack chassis having an enclosure with a power shelf and a busbar for one or more sleds of the enclosure, according to at least one embodiment. FIG. 3A illustrates that each of the enclosures 122B, 122C may include its own power shelf 124A, 124C and may include its own enclosure busbar 118X to provide power for respective one or more sleds 120 of the enclosures 122B, 122C. FIG. 3A also illustrates a side view of a non-powered rack chassis 104X so that a front of the non-powered rack chassis 104X faces the hot aisle 128 side of the datacenter 100 and a rear of the non-powered rack chassis 104X faces the cold aisle 130 side of the datacenter 100. FIG. 3A illustrates that the enclosure 122B, 122C may be vertically 304A stacked and that the power shelf 124B, 124C, as well as the sled 120 may also be vertically 304A staked and may extend horizontally 304B in the stack.

FIG. 3B illustrates further power distribution aspects 350 in a system for a non-powered rack chassis having an enclosure with a power shelf and a busbar for one or more sleds of the enclosure, according to at least one embodiment. The power distribution aspects 350 include that the power shelf 124A, 124C may be configured for converting alternating current (AC) power to direct current (DC) power for distribution to the enclosure busbar 118X. For instance, a power shelf 124 may include power input features 354, power distribution (dist.) features 356, and power conditioning (cond.) features 358. The power input features 354 may include the power I/P 254 and a power connector 352 to connect to a power source 252. The power input features 354 may include internal circuitry, including any input power protection circuits, to provide the received power to the power conditioning features 358.

The power conditioning features 358 may perform one or more of power conversion (using converters including transformers and rectifiers), power adjustment (using correctors including limiters and programmable logic controllers (PLCs), power monitors (using feedback circuits), and power balancers (using redundancy, serial, and parallel circuits). The power distribution features 356 may include the enclosure busbar 118X and circuitry between the power distribution features 356 to the enclosure busbar 118X, including any output protection circuits. The one or more sleds 120 may include one or more compute devices 360 and one or more other devices 362. At least the other devices may be cooling devices, such as the fans 258. The fans 258 may be used to cool the compute devices 360 and, altogether, the compute devices 360 and other devices 362 are provided to perform a workload in the datacenter 100.

FIG. 3B also illustrates that the enclosure busbar 118X may be used to carry DC power from the power shelf 124A, 124C to the one or more sleds 120. A power shelf 124 may be further configured to power at least one additional enclosure having non-powered sleds installed within a non-powered rack chassis 104XA, 104XB, as illustrated and described in connection with at least FIG. 2A and the enclosures 122A, 122C. Individual ones of the one or more sleds 120 may be configured to include the individual compute device 360, which may include an operating system (OS). When there are multiple compute devices 360, each may include its own OS and may perform independent aspects of a workload in a datacenter 100.

FIGS. 1-3B illustrates that an enclosure 122-122C having dimensions 202 to fit within a non-powered rack chassis 104X-104XB and having or associated therewith a power shelf 124-124C can distribute power for one or more sleds 120 within the enclosure 122-122C using at least one enclosure busbar 118X of the power shelf 124-124C. The enclosure may include the aforementioned plug-and-play configuration for plug-and-play installation, with respect to coupling of an enclosure 122-122C to a power source 252. The plug-and-play installation may be a push-and-pull association 132 of an enclosure 122-122C within a non-powered rack chassis 104X-104XB. The plug-and-play installation may also provide the power for the one or more sleds using a power shelf 124-124C and an enclosure busbar 118X while within the non-powered rack chassis 104X-104XB.

The enclosure 122-122C may be configured to be installed into a non-powered rack chassis 104X-104XC from a hot aisle 128 side of a datacenter 100, relative to a cold aisle 130 side of the datacenter 100. The enclosure 122-122C may be such that one or more fans 258 provided may be configured for directional changes. The one or more fans 258 may be switched so that airflow for cooling within an enclosure 122-122C flows from a cold aisle 130 side to the hot aisle 128 side in the datacenter 100. The enclosure 122-122C may be such that a power shelf 124-124C may be configured to convert AC power to DC power for distribution to an enclosure busbar 118X.

The enclosure 122-122C may be such that the enclosure busbar 118X can carry DC power from the power shelf 124-124C to one or more sleds 120. A power shelf 124-124C may be further configured to power at least one additional enclosure 122B having non-powered sleds, that is non-powered itself, and that is installed within the non-powered rack chassis 104X-104XB. The enclosure 122-122C may be such that individual ones of one or more sleds 120 provided therein may be configured to include an individual compute device 360 having an independent operating system (OS).

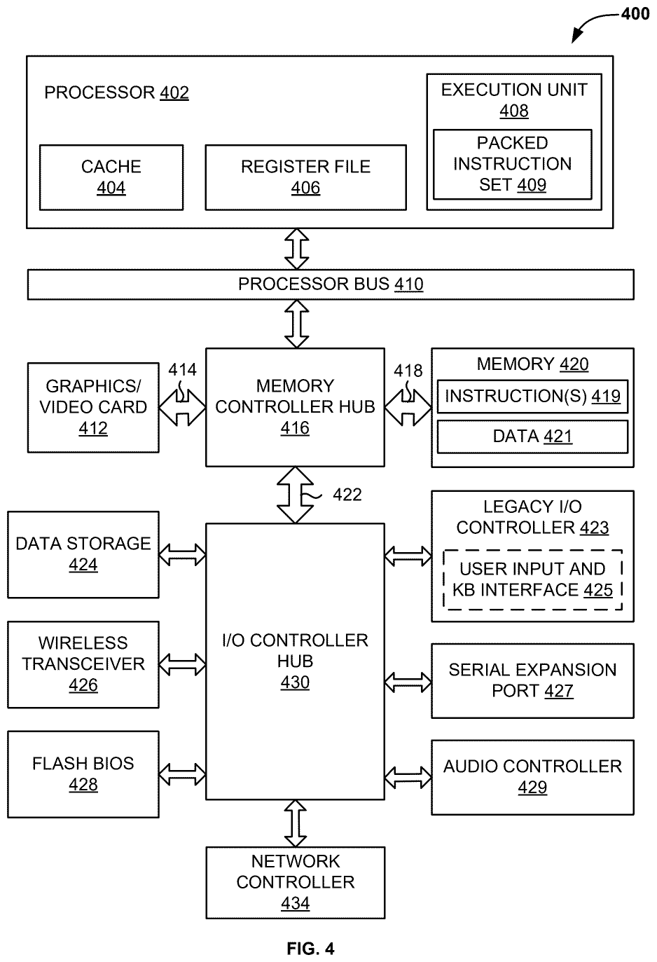

FIG. 4 illustrates computer and processor aspects 400 for a non-powered rack chassis having an enclosure with a power shelf and a busbar for one or more sleds of the enclosure, according to at least one embodiment. The computer and processor aspects 400 may be performed by one or more processors that include a system-on-a-chip (SOC) or some combination thereof formed with a processor that may include execution units to execute an instruction, according to at least one embodiment. Such one or more processors may include CPUs, data processing units (DPUs), and graphics processing units (GPUs) and may be within the power shelf 124. For instance, the one or more processors may be part of the power conditioning features 358 of the power shelf 124 and may be used, in part, in instructing changes to the power distribution feature 356. In at least one embodiment, the computer and processor aspects 400 may be part of the compute devices 360 in a sled 120 and may be provided to perform a workload. The computer and processor aspects 400 may benefit from power provided from a power shelf 124 of an enclosure 122, in a non-powered rack chassis 104X.

A power shelf 124 may include circuit feedback from the power distribution features 356, the power input features 354, and the power conditioning features 358. The power shelf 124 may be able to respond to such circuit feedback by digital input to one or more of the features 354-358. For instance, the digital input may be provided to cause voltage, amperage, or other changes to balance the input or load for an enclosure 122 and for any connected or additional enclosures.

In at least one embodiment, the computer and processor aspects 400 may include, without limitation, a component, such as a processor 402 to employ execution units including logic to perform algorithms for process data, in accordance with the present disclosure, such as in at least one embodiment described herein. In at least one embodiment, the computer and processor aspects 400 may include processors, such as PENTIUM® Processor family, Xeon™, Itanium®, XScale™ and/or StrongARM™, Intel® Core™, or Intel® Nervana™ microprocessors available from Intel Corporation of Santa Clara, California, although other systems (including PCs having other microprocessors, engineering workstations, set-top boxes and like) may also be used. In at least one embodiment, the computer and processor aspects 400 may execute a version of WINDOWS® operating system available from Microsoft® Corporation of Redmond, Wash., although other operating systems (UNIX® and Linux®, for example), embedded software, and/or graphical user interfaces, may also be used.

Embodiments may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (“DSP”), a system on a chip, network computers (“NetPCs”), set-top boxes, network hubs, wide area network (“WAN”) switches, or any other system that may perform one or more instructions in accordance with at least one embodiment.

In at least one embodiment, the computer and processor aspects 400 may include, without limitation, a processor 402 that may include, without limitation, one or more execution units 408 to perform aspects according to techniques described with respect to at least one or more of FIGS. 1-3B and 5-7 herein. In at least one embodiment, the computer and processor aspects 400 is a single processor desktop or server system, but in another embodiment, the computer and processor aspects 400 may be a multiprocessor system.

In at least one embodiment, the processor 402 may include, without limitation, a complex instruction set computer (“CISC”) microprocessor, a reduced instruction set computing (“RISC”) microprocessor, a very long instruction word (“VLIW”) microprocessor, a processor implementing a combination of instruction sets, or any other processor device, such as a digital signal processor, for example. In at least one embodiment, a processor 402 may be coupled to a processor bus 410 that may transmit data signals between processor 402 and other components in computer and processor aspects 400.

In at least one embodiment, a processor 402 may include, without limitation, a Level 1 (“L1”) internal cache memory (“cache”) 404. In at least one embodiment, a processor 402 may have a single internal cache or multiple levels of internal cache. In at least one embodiment, cache 404 may reside externally to a processor 402. Other embodiments may also include a combination of both internal and external caches depending on particular implementation and needs. In at least one embodiment, a register file 406 may store different types of data in various registers including, without limitation, integer registers, floating point registers, status registers, and an instruction pointer register.

In at least one embodiment, an execution unit 408, including, without limitation, logic to perform integer and floating point operations, also resides in a processor 402. In at least one embodiment, a processor 402 may also include a microcode (“ucode”) read only memory (“ROM”) that stores microcode for certain macro instructions. In at least one embodiment, an execution unit 408 may include logic to handle a packed instruction set 409.

In at least one embodiment, by including a packed instruction set 409 in an instruction set of a general-purpose processor, along with associated circuitry to execute instructions, operations used by many multimedia applications may be performed using packed data in a processor 402. In at least one embodiment, many multimedia applications may be accelerated and executed more efficiently by using a full width of a processor's data bus for performing operations on packed data, which may eliminate a need to transfer smaller units of data across that processor's data bus to perform one or more operations one data element at a time.

In at least one embodiment, an execution unit 408 may also be used in microcontrollers, embedded processors, graphics devices, DSPs, and other types of logic circuits. In at least one embodiment, the computer and processor aspects 400 may include, without limitation, a memory 420. In at least one embodiment, a memory 420 may be a Dynamic Random Access Memory (“DRAM”) device, a Static Random Access Memory (“SRAM”) device, a flash memory device, or another memory device. In at least one embodiment, a memory 420 may store instruction(s) 419 and/or data 421 represented by data signals that may be executed by a processor 402.

In at least one embodiment, a system logic chip may be coupled to a processor bus 410 and a memory 420. In at least one embodiment, a system logic chip may include, without limitation, a memory controller hub (“MCH”) 416, and processor 402 may communicate with MCH 416 via processor bus 410. In at least one embodiment, an MCH 416 may provide a high bandwidth memory path 418 to a memory 420 for instruction and data storage and for storage of graphics commands, data, and textures. In at least one embodiment, an MCH 416 may direct data signals between a processor 402, a memory 420, and other components in the computer and processor aspects 400 and to bridge data signals between a processor bus 410, a memory 420, and a system I/O interface 422. In at least one embodiment, a system logic chip may provide a graphics port for coupling to a graphics controller. In at least one embodiment, an MCH 416 may be coupled to a memory 420 through a high bandwidth memory path 418 and a graphics/video card 412 may be coupled to an MCH 416 through an Accelerated Graphics Port (“AGP”) interconnect 414.

In at least one embodiment, the computer and processor aspects 400 may use a system I/O interface 422 as a proprietary hub interface bus to couple an MCH 416 to an I/O controller hub (“ICH”) 430. In at least one embodiment, an ICH 430 may provide direct connections to some I/O devices via a local I/O bus. In at least one embodiment, a local I/O bus may include, without limitation, a high-speed I/O bus for connecting peripherals to a memory 420, a chipset, and processor 402. Examples may include, without limitation, an audio controller 429, a firmware hub (“flash BIOS”) 428, a wireless transceiver 426, a data storage 424, a legacy I/O controller 423 containing user input and keyboard interfaces 425, a serial expansion port 427, such as a Universal Serial Bus (“USB”) port, and a network controller 434. In at least one embodiment, data storage 424 may comprise a hard disk drive, a floppy disk drive, a CD-ROM device, a flash memory device, or other mass storage device.

In at least one embodiment, FIG. 4 illustrates computer and processor aspects 400, which includes interconnected hardware devices or “chips”, whereas in other embodiments, FIG. 4 may illustrate an exemplary SoC. In at least one embodiment, devices illustrated in FIG. 4 may be interconnected with proprietary interconnects, standardized interconnects (e.g., PCIe®) or some combination thereof. In at least one embodiment, one or more components of the computer and processor aspects 400 that are interconnected using compute express link (CXL) interconnects.

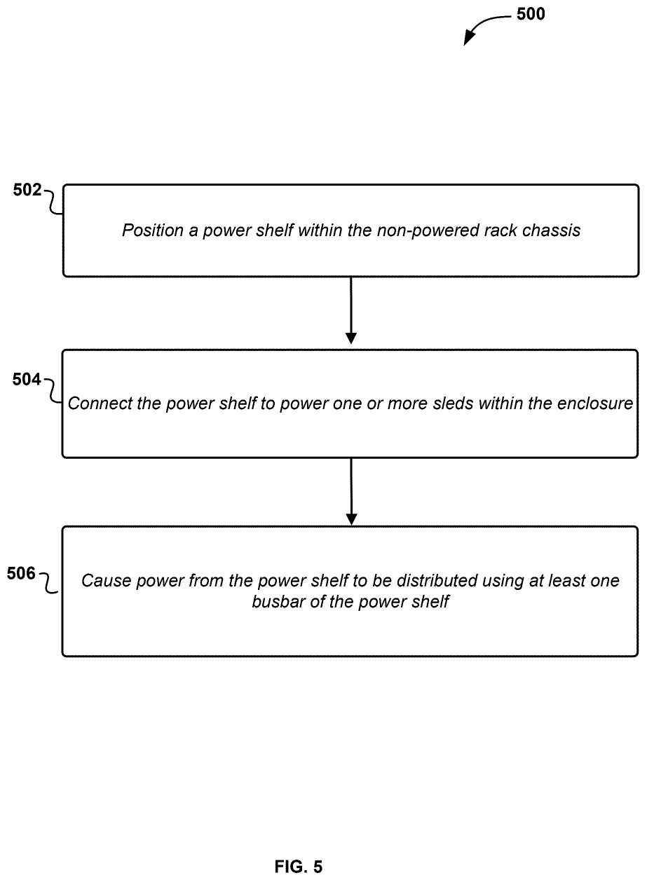

FIG. 5 illustrates a process flow or method 500 for a non-powered rack chassis, according to at least one embodiment. The method 500 may include a step to position 502 a power shelf within the non-powered rack chassis. This step may include a step of allowing an enclosure having a power shelf to fit within a non-powered rack chassis. For instance, the enclosure may include a shape, supported by its dimensions and tolerances, to fit within the non-powered rack chassis. This step may include manufacture or installation of the enclosure with respect to the non-powered rack chassis. For instance, a suitable enclosure may be chosen to have configuration to fit within association features of a non-powered rack chassis. In one example, dimensions of the enclosure may be based in part on a compute potential intended for the non-powered rack chassis. The compute potential may be based in part on a workload to be performed using the compute devices within the non-powered rack chassis. The dimensions may include tolerances to allow the fit within the non-powered rack chassis.

The method 500 may include a step to connect 504 the power shelf to power one or more sleds within the enclosure. This may include a sub-step to allow a power shelf to provide power from within the enclosure. For instance, the power shelf can be suited to provide the power for one or more sleds. The sleds may include the compute devices and may include other devices. The step to allow a power shelf to provide power may include a step to ensure that a power I/P of the power shelf is suitably connected to a power source of a datacenter.

The method 500 may include determining or verifying that the devices to be powered are provided within the sleds for within servers or trays of the sleds. The method 500 may include a step to cause 506 power from the power shelf to be distributed using at least one busbar of the power shelf. The power may be distributed from the power shelf to the one or more sleds using the at least one busbar of the power shelf. In one instance, for safety reasons, it is possible that the power shelf being coupled to the power source alone may not automatically provide power to the one or more sleds of the enclosure. There may be a delay or a sequence of events to ensure that power is stable and corresponding to the limits for the requisite compute devices and for the other devices. Further, it is possible to automatically run through the sequence of events to cause power from the power shelf to be available on the busbar of the power shelf and to power the sleds after the step to connect 504 the power shelf to power one or more sleds within the enclosure and without further action.

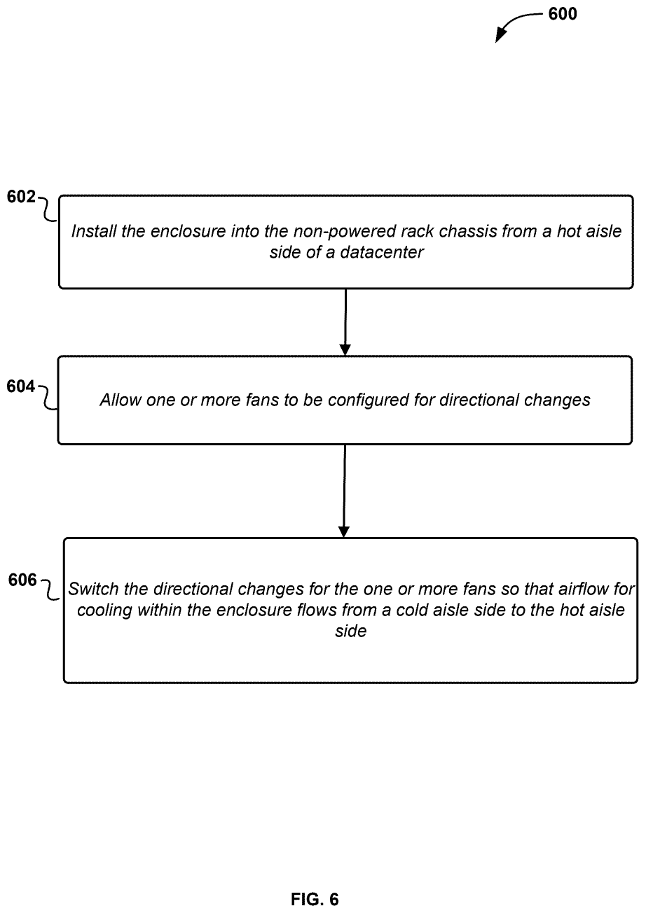

FIG. 6 illustrates yet another process flow or method 600 in a system of a non-powered rack chassis, according to at least one embodiment. The method 600 may be in support of the method 500 in FIG. 5. For example, the method 600 may include a step to install 602 the enclosure into the non-powered rack chassis from a hot aisle side of a datacenter. The method 600 may include a step to allow 604 one or more fans to change direction for directional changes associated with air flow in the enclosure. The one or more fans may be located in the one or more sleds and even in the power shelf. The method 600 may include verifying or determining that cooling is required for devices. The method 600 may include a step to switch 606 the directional changes for the one or more fans so that airflow for cooling within the enclosure flows from a cold aisle side to the hot aisle side.

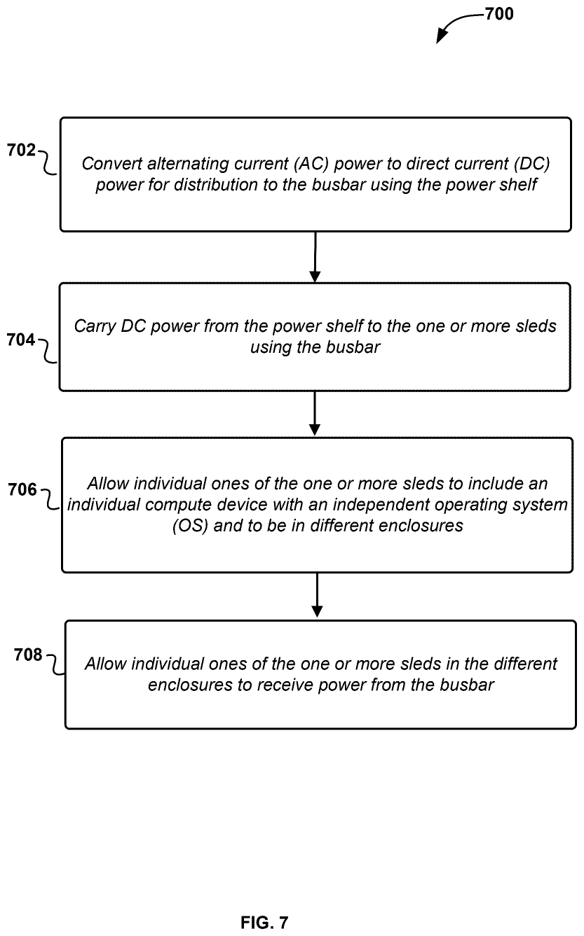

FIG. 7 illustrates a further process flow or method 700 in a system having a non-powered rack chassis, according to at least one embodiment. The method 700 may be in support of one or more of the method 500 in FIG. 5 or the method 600 in FIG. 6. For example, the method 700 may include a step to convert 702 AC power to DC power for distribution to the busbar using the power shelf. This converting 702 step may be in support of the step to connect 504 a power shelf to power one or more sleds, in the method 500 of FIG. 5. The method 700 may include a step to carry 704 DC power from the power shelf to the one or more sleds using the busbar. The step to carry 704 power may extend to multiple enclosures. For instance, the power shelf may be further configured (such as by having a busbar with sufficient length) to reach additional enclosures and to power at least one additional enclosure. The additional enclosure may also be such that it may include non-powered sleds installed within the non-powered rack chassis. The power from the power shelf can address the power required in such non-powered sleds. Any of the methods 500-700 may be found in the manufacturing of enclosures for a non-powered rack chassis, where the enclosures include a power shelf and a busbar for one or more sleds of the enclosures. Further, any of the methods 500-700 may be found in use of the enclosures with the non-powered rack chassis and including the power shelf and the busbar for one or more sleds of the enclosures.

As used herein, a non-powered sled may not have a native or inbuilt power source or a native or inbuilt power conditioning capability. The power conditioning may be provided from the power shelf. The method 700 may include a step to allow 706 individual ones of the one or more sleds to include an individual compute device. The individual compute device may include an independent OS and may be in different enclosures. There may be a step in the method 700 for determining or verifying that a workload is to be performed in different enclosures. For instance, the workload may be substantial and may need multiple compute devices spread across different enclosures. The method 700 may include a step to allow 708 individual ones of the one or more sleds in the different enclosures to receive power from the busbar.

One or more of the methods 500-700 may include a step or sub-step for allowing the enclosure to be configured for a plug-and-play installation. The plug-and-play installation may be with respect to coupling of the enclosure to a power source. The coupling may be by a push-and-pull association of the enclosure within the non-powered rack chassis. The plug-and-play installation may also be with respect to providing the power for the one or more sleds using the power shelf and the busbar while the enclosure is within the non-powered rack chassis.

One or more of the methods 500-700 may include a step or sub-step for allowing the enclosure to be configured for installation into the non-powered rack chassis from a hot aisle side of a datacenter. One or more of the methods 500-700 may include a step or sub-step for allowing one or more fans to include configuration for directional changes in the one or more sleds or the power shelf. The one or more fans may be switched so that airflow for cooling within the enclosure may flow from a cold aisle side to the hot aisle side.

One or more of the methods 500-700 may include a step or sub-step for allowing the power shelf to be configured to convert AC power to DC power for distribution to the busbar. One or more of the methods 500-700 may include a step or sub-step for carrying DC power from the power shelf to the one or more sleds using the busbar. One or more of the methods 500-700 may include a step or sub-step for the power shelf to include further configured to power at least one additional enclosure comprising non-powered sleds installed within the non-powered rack chassis.

One or more of the methods 500-700 may include a step or sub-step for individual ones of the one or more sleds are configured to include an individual compute device. The individual computing device may include an independent OS. One or more of the methods 500-700 may include a step or sub-step for performing, using the power shelf within the enclosure, a plug-and-play installation for the enclosure with respect to coupling of the enclosure to a power source, by a push-and-pull association of the enclosure within the non-powered rack chassis. One or more of the methods 500-700 may include a step or sub-step for providing the power for the one or more sleds using the power shelf and the busbar while the enclosure is within the non-powered rack chassis. Further, one or more of the methods 500-700 may include a step or sub-step for installing the enclosure into the non-powered rack chassis from a hot aisle side of a datacenter.

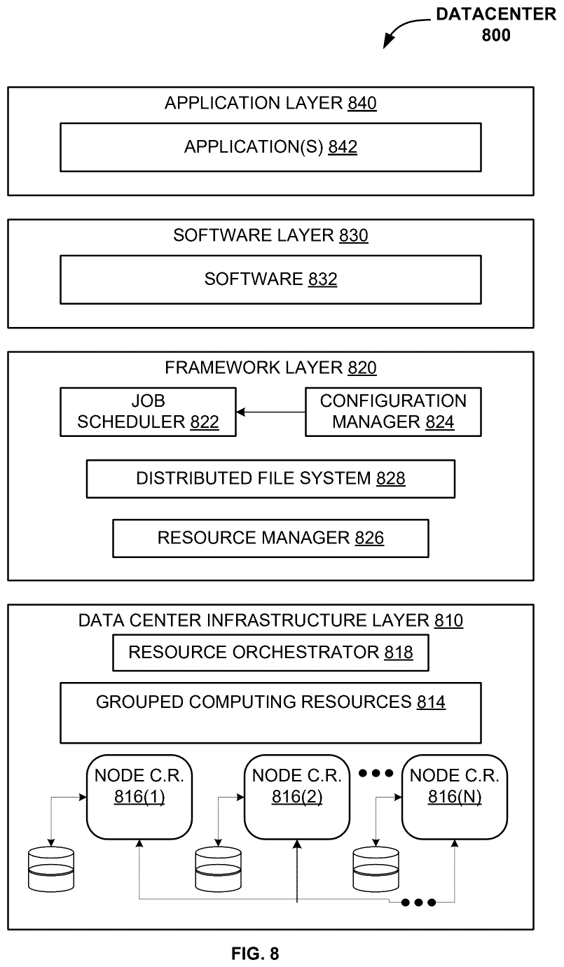

FIG. 8 illustrates an example datacenter 800 to apply at least one embodiment in FIGS. 1-7. In at least one embodiment, datacenter 800 includes a datacenter infrastructure layer 810, a framework layer 820, a software layer 830, and an application layer 840. The example datacenter 800 may include a non-powered rack chassis with an enclosure associated with a power shelf having dimensions to fit within the enclosure or to fit within the non-powered rack chassis. The power shelf can receive power, condition power for compute or other devices, and distribute the power for the compute or other devices.

An enclosure may be as described with respect to FIGS. 1-7, in which circuit boards of the enclosure may have processors (such as CPUs, GPUs, DPUs, or the like (also described as node computing resources (node C.R.s 816(1)-816(N)), and other devices described with respect to the datacenter infrastructure layer 810. The enclosure is capable of performing workloads using the circuit board therein and may be provided for on-the-fly computing or to support changing workload demands in a datacenter.

In at least one embodiment, as shown in FIG. 8, datacenter infrastructure layer 810 may include a resource orchestrator 818, grouped computing resources 814, and node computing resources (“node C.R.s”) 816(1)-816(N), where “N” represents any whole, positive integer. In at least one embodiment, node C.R.s 816(1)-816(N) may include, but are not limited to, any number of central processing units (“CPUs”) or other processors (including accelerators, field programmable gate arrays (FPGAs), graphics processors, etc.), memory devices (e.g., dynamic read-only memory), storage devices (e.g., solid state or disk drives), network input/output (“NW I/O”) devices, network switches, virtual machines (“VMs”), power modules, and cooling modules, etc. In at least one embodiment, one or more node C.R.s from among node C.R.s 816(1)-816(N) may be a server having one or more of above-mentioned computing resources.

In at least one embodiment, grouped computing resources 814 may include separate groupings of node C.R.s housed within one or more racks (not shown), or many racks housed in datacenters at various geographical locations (also not shown). Separate groupings of node C.R.s within grouped computing resources 814 may include grouped compute, network, memory or storage resources that may be configured or allocated to support one or more workloads. In at least one embodiment, several node C.R.s including CPUs or processors may be grouped within one or more racks to provide compute resources to support one or more workloads. In at least one embodiment, one or more racks may also include any number of power modules, cooling modules, and network switches, in any combination.

In at least one embodiment, resource orchestrator 818 may configure or otherwise control one or more node C.R.s 816(1)-816(N) and/or grouped computing resources 814. In at least one embodiment, resource orchestrator 818 may include a software design infrastructure (“SDI”) management entity for datacenter 800. In at least one embodiment, resource orchestrator 818 may include hardware, software or some combination thereof.

In at least one embodiment, as shown in FIG. 8, framework layer 820 includes a job scheduler 822, a configuration manager 824, a resource manager 826 and a distributed file system 828. In at least one embodiment, framework layer 820 may include a framework to support software 832 of software layer 830 and/or one or more application(s) 842 of application layer 840. In at least one embodiment, software 832 or application(s) 842 may respectively include web-based service software or applications, such as those provided by Amazon Web Services, Google Cloud and Microsoft Azure. In at least one embodiment, framework layer 820 may be, but is not limited to, a type of free and open-source software web application framework such as Apache Spark™ (hereinafter “Spark”) that may use distributed file system 828 for large-scale data processing (e.g., “big data”). In at least one embodiment, job scheduler 822 may include a Spark driver to facilitate scheduling of workloads supported by various layers of datacenter 800. In at least one embodiment, configuration manager 824 may be capable of configuring different layers such as software layer 830 and framework layer 820 including Spark and distributed file system 828 for supporting large-scale data processing. In at least one embodiment, resource manager 826 may be capable of managing clustered or grouped computing resources mapped to or allocated for support of a distributed file system 828 and a job scheduler 822. In at least one embodiment, clustered or grouped computing resources may include the grouped computing resources 814 at the datacenter infrastructure layer 810. In at least one embodiment, resource manager 826 may coordinate with resource orchestrator 818 to manage these mapped or allocated computing resources.

In at least one embodiment, software 832 included in software layer 830 may include software used by at least portions of node C.R.s 816(1)-816(N), grouped computing resources 814, and/or distributed file system 828 of framework layer 820. The one or more types of software may include, but are not limited to, Internet web page search software, e-mail virus scan software, database software, and streaming video content software.

In at least one embodiment, application(s) 842 included in application layer 840 may include one or more types of applications used by at least portions of node C.R.s 816(1)-816(N), grouped computing resources 814, and/or distributed file system 828 of framework layer 820. One or more types of applications may include, but are not limited to, any number of a genomics application, a cognitive compute, and a machine learning application, including training or inferencing software, machine learning framework software (e.g., PyTorch, TensorFlow, Caffe, etc.) or other machine learning applications used in conjunction with one or more embodiments.

In at least one embodiment, any of the configuration manager 824, the resource manager 826, and the resource orchestrator 818 may implement any number and type of self-modifying actions based on any amount and type of data acquired in any technically feasible fashion. In at least one embodiment, self-modifying actions may relieve a datacenter operator of datacenter 800 from making possibly bad configuration decisions and possibly avoiding underused and/or poor performing portions of a datacenter.

In at least one embodiment, a datacenter 800 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to datacenter 800. In at least one embodiment, trained machine learning models corresponding to one or more neural networks may be used to infer or predict information using resources described above with respect to datacenter 800 by using weight parameters calculated through one or more training techniques described herein.

In at least one embodiment, datacenter may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or perform inferencing of information, such as image recognition, speech recognition, or other artificial intelligence services.

Other variations are within the spirit of present disclosure. Thus, while disclosed techniques are susceptible to various modifications and alternative constructions, certain illustrated embodiments thereof are shown in drawings and have been described in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. In at least one embodiment, use of the term ‘set’ (e.g., “a set of items”) or “subset” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, the term “plurality” indicates a state of being plural (e.g., “a plurality of items” indicates multiple items). In at least one embodiment, the number of items in a plurality is at least two, but can be more when so indicated either explicitly or by context. Further, unless stated otherwise or otherwise clear from context, the phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in the form of a computer program comprising a plurality of instructions executable by one or more processors.

In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause the computer system to perform operations described herein. In at least one embodiment, a set of non-transitory computer-readable storage media comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors—for example, a non-transitory computer-readable storage medium store instructions and a main central processing unit (“CPU”) executes some of the instructions while a graphics processing unit (“GPU”) executes other instructions. In at least one embodiment, different components of a computer system have separate processors and different processors execute different subsets of instructions.

In at least one embodiment, an arithmetic logic unit is a set of combinational logic circuitry that takes one or more inputs to produce a result. In at least one embodiment, an arithmetic logic unit is used by a processor to implement mathematical operations such as addition, subtraction, or multiplication. In at least one embodiment, an arithmetic logic unit is used to implement logical operations such as logical AND/OR or XOR. In at least one embodiment, an arithmetic logic unit is stateless, and made from physical switching components such as semiconductor transistors arranged to form logical gates. In at least one embodiment, an arithmetic logic unit may operate internally as a stateful logic circuit with an associated clock. In at least one embodiment, an arithmetic logic unit may be constructed as an asynchronous logic circuit with an internal state not maintained in an associated register set. In at least one embodiment, an arithmetic logic unit is used by a processor to combine operands stored in one or more registers of the processor and produce an output that can be stored by the processor in another register or a memory location.

In at least one embodiment, as a result of processing an instruction retrieved by the processor, the processor presents one or more inputs or operands to an arithmetic logic unit, causing the arithmetic logic unit to produce a result based at least in part on an instruction code provided to inputs of the arithmetic logic unit. In at least one embodiment, the instruction codes provided by the processor to the ALU are based at least in part on the instruction executed by the processor. In at least one embodiment, combinational logic in the ALU processes the inputs and produces an output which is placed on a bus within the processor. In at least one embodiment, the processor selects a destination register, memory location, output device, or output storage location on the output bus so that clocking the processor causes the results produced by the ALU to be sent to the desired location.

Accordingly, in at least one embodiment, computer systems are configured to implement one or more services that singly or collectively perform operations of processes described herein and such computer systems are configured with applicable hardware and/or software that allow performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to the practice of the disclosure.

In description and claims, terms “coupled” and “connected,” along with their derivatives, may be used. It should be understood that these terms may not be intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, a “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. In at least one embodiment, terms “system” and “method” are used herein interchangeably insofar as the system may embody one or more methods and methods may be considered a system.

In present document, references may be made to obtaining, acquiring, receiving, or inputting analog or digital data into a subsystem, computer system, or computer-implemented machine. In at least one embodiment, the process of obtaining, acquiring, receiving, or inputting analog and digital data can be accomplished in a variety of ways, such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing an entity to acquiring entity. References may also be made to providing, outputting, transmitting, sending, or presenting analog or digital data. In at least one embodiment, processes of providing, outputting, transmitting, sending, or presenting analog or digital data can be accomplished by transferring data as an input or output parameter of a function call, a parameter of an application programming interface or interprocess communication mechanism.

Although descriptions herein set forth example implementations of described techniques, other architectures may be used to implement described functionality, and are intended to be within scope of this disclosure. Furthermore, although specific distributions of responsibilities may be defined above for purposes of description, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A system for powering a non-powered rack chassis, comprising:
an enclosure shaped to fit within the non-powered rack chassis;
a power shelf to provide power from within the enclosure or within the power shelf; and
at least one busbar of the power shelf to distribute the power from the power shelf to one or more sleds of the non-powered rack chassis.

2. The system of claim 1, wherein the enclosure is configured for a plug-and-play installation, with respect to coupling of the enclosure to a power source, by a push-and-pull association of the enclosure within the non-powered rack chassis, and with respect to providing the power for the one or more sleds using the power shelf and the busbar while the enclosure is within the non-powered rack chassis.

3. The system of claim 1, wherein the enclosure is configured to be installed into the non-powered rack chassis from a hot aisle side of a datacenter.

4. The system of claim 1, further comprising:
one or more fans configured for directional changes, wherein the one or more fans is switched so that airflow for cooling within the enclosure flows from a cold aisle side to a hot aisle side.

5. The system of claim 1, wherein the power shelf is configured to convert alternating current (AC) power to direct current (DC) power for distribution via the busbar.

6. The system of claim 1, wherein the busbar is to carry direct current (DC) power from the power shelf to the one or more sleds and wherein the power shelf is further configured to power at least one additional enclosure comprising non-powered sleds installed within the non-powered rack chassis.

7. The system of claim 6, wherein individual ones of the one or more sleds are configured to comprise an individual compute device comprising an independent operating system (OS).

8. The system of claim 1, wherein the power shelf is within the enclosure.

9. A power shelf comprising at least one bus bar and positioned to be within an enclosure which is shaped to fit within a non-powered rack chassis, the power shelf configured to distribute power for one or more sleds within the enclosure using the at least one busbar.

10. The power shelf of claim 9, further comprising:
a plug-and-play configuration for plug-and-play installation, with respect to coupling of the enclosure to a power source, wherein the plug-and-play installation is a push-and-pull association of the enclosure within the non-powered rack chassis, and wherein the plug-and-play installation is also to provide the power for the one or more sleds using the power shelf and the busbar while within the non-powered rack chassis.

11. The power shelf of claim 9, wherein the enclosure is configured to be installed into the non-powered rack chassis from a hot aisle side of a datacenter.

12. The power shelf of claim 9, further comprising:
one or more fans configured for directional changes, wherein the one or more fans is switched so that airflow for cooling within the enclosure flows from a cold aisle side to a hot aisle side.

13. The power shelf of claim 9, wherein the power shelf is configured to convert alternating current (AC) power to direct current (DC) power for distribution to the busbar.

14. The power shelf of claim 9, wherein the busbar is to carry direct current (DC) power from the power shelf to the one or more sleds and wherein the power shelf is further configured to power at least one additional enclosure comprising non-powered sleds installed within the non-powered rack chassis.

15. The power shelf of claim 9, wherein individual ones of the one or more sleds are configured to comprise an individual compute device comprising an independent operating system (OS).

16. A method for powering a non-powered rack chassis, comprising:
positioning a power shelf within the non-powered rack chassis;
connecting the power shelf to power one or more sleds within an enclosure of the non-powered rack chassis; and
causing power from the power shelf to be distributed using at least one busbar of the power shelf.

17. The method of claim 16, further comprising:
performing plug-and-play installation for the enclosure with respect to coupling of the enclosure to a power source, by a push-and-pull association of the enclosure within the non-powered rack chassis; and
providing the power for the one or more sleds using the power shelf and the busbar while the enclosure is within the non-powered rack chassis.

18. The method of claim 16, further comprising:
installing the enclosure into the non-powered rack chassis from a hot aisle side of a datacenter.

19. The method of claim 16, further comprising:
allowing one or more fans to be configured for directional changes; and
switching the directional changes for the one or more fans so that airflow for cooling within the enclosure flows from a cold aisle side to a hot aisle side.

20. The method of claim 16, further comprising one or more of:
converting alternating current (AC) power to direct current (DC) power for distribution to the busbar using the power shelf;
carrying DC power from the power shelf to the one or more sleds using the busbar, wherein the power shelf is further configured to power at least one additional enclosure comprising non-powered sleds installed within the non-powered rack chassis;
allowing individual ones of the one or more sleds to comprise an individual compute device comprising an independent operating system (OS); or
allowing the power shelf to be within the enclosure.
